(19) United States
(12) Patent Application Publication
(10) Pub. No.: US 2010/0177469 A1
(43) Pub. Date: Jul. 15, 2010

(54) ASSEMBLY STRUCTURE OF ELECTRONIC DEVICE

(75) Inventor: Keng-Ping Wang, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTEK COMPUTER INC., Taipei (TW)

(21) Appl. No.: 12/649,336

(22) Filed: Dec. 30, 2009

(30) Foreign Application Priority Data
Jan. 9, 2009 (TW) 98100615

(51) Int. Cl. H05K 5/00

(52) U.S. Cl. 361/679.01

(57) ABSTRACT

An assembly structure of electronic device includes a first case, a second case, at least one assembly element and at least one locking element. The first case has at least one first combining portion, the second case has at least one second combining portion, and the assembly element has a plurality of positioning portions and a locking portion. The positioning portions engage with the second case to position the assembly element on the second case. The locking element passes through the first combining portion and the second combining portion and fixed in the locking portion. Such as to provide an intact appearance and preferred combination stability.

### CROSS-REFERENCE TO RELATED APPLICATION

This application claims the priority benefit of Taiwan application serial no. 98100615, filed on Jan. 9, 2009. The entirety of the above-mentioned patent application is hereby incorporated by reference herein and made a part of specification.

### BACKGROUND OF THE INVENTION

1. Field of the Invention

The invention relates to an electronic device and, more particularly, to an electronic device having preferred strengthen assembly structure.

2. Description of the Related Art

As electronic devices are designed to be lighter, slimmer, shorter and smaller, the thickness of a housing of the electronic device becomes thinner and thinner. The housing of the electronic device usually comprises an upper case and a lower case that assembled to each other, and electronic elements such as control circuits, loudspeakers and antennas are disposed in a containing space formed between the upper case and the lower case.

Generally, both the upper case and the lower case have assembling holes, and screws assemble the upper case and the lower case by passing through the assembling holes and being fixed. When it comes to practice, electronic devices with aforesaid assembling structure are inevitably facing a dilemma between lightness and strength in the end. Taking an electronic device which has a housing of 1.2 centimeters of thickness for example, to prevent weight adding or plastic shrinking due to increasing of the thickness of the housing, the thickness around the assembling holes of the upper case and the lower case should be half of the whole thickness such as 0.6 centimeters. Within such measure, plastic shrinking may be avoided, and the whole thickness and the appearance of the housing are not affected. However, strength of the assembling structure is uncertain.

FIG. 1 is an exploded diagram showing an upper case, a lower case and a screw in a conventional electronic device. As shown in FIG. 1, the thickness of the upper case 110 and the lower case 120 of the electronic device 100 are small, and the screw 130 has a fixed screw pitch. When the screw 130 passes through the assembling holes of the upper case 110 and the lower case 120 to assemble the upper case 110 and the lower case 120, screwed teeth of the screw 130 are hardly to get engaged completely, because of small thickness of the upper case 110 and the lower case 120 or the overlarge screw pitch. Thus, the upper case 110 and the lower case 120 may easily loose and drop from each other, or the teeth of the screw 130 be broken.

Although an auxiliary fixing element may be used to increase the locking thickness of the upper case 110 and the lower case 120 for the screw 130, hands or tools are needed to position the fixing element for insertion of the screw. However, since the upper case 110 usually covers the lower case 120, the hands or the tools may awkwardly reach the fixing element. Thus, the fixing element may drop, and the combination firmness and convenience of the upper case 110 and the lower case 120 are not assured.

FIG. 2 is a schematic diagram showing a lower case in another conventional electronic device. As shown in FIG. 2, in another conventional method, the thickness of part of the lower case 220 where the assembling holes are formed (or the upper case, not shown) is increased. However, since the upper case (not shown) and the lower case 220 of the electronic device are usually made of plastic, and they are usually manufactured in an injection molding process, the plastic particles may shrink after a demoulding process, and part of the case may sink at the position where the thickness is large, and the appearance of the surface and the assembling effect are affected.

### BRIEF SUMMARY OF THE INVENTION

The invention provides an assembly structure of electronic device with an intact appearance and preferred combination stability.

The invention discloses an assembly structure of electronic device including a first case, a second case, at least one assembly element and at least one locking element. The first case has at least one first combining portion, and the second case has at least one second combining portion. Each of the assembly elements has at least one positioning portion and a locking portion, and the positioning portion combine with the second case to position the assembly element on the second case. The locking element passes through the first combining portion of the first case and the second combining portion of the second case, and fixes in the locking portion of the assembly element.

In the assembly structure of electronic device in an embodiment of the invention, the first combining portion and the second combining portion have corresponding threaded holes, respectively, and the locking portion has an assembling hole.

In the assembly structure of electronic device in an embodiment of the invention, the second case has an outer surface and an indentation portion formed at the outer surface. The first case has a contact edge and a protrusion portion protruding from the contact edge. The protrusion portion is received in the indentation portion.

In the assembly structure of electronic device in an embodiment of the invention, the second case has two mounts, and each of the mounts engage with the positioning portion of the assembly element. A bottom surface of the positioning portion abuts against an edge of the second case.

In the assembly structure of electronic device in an embodiment of the invention, two corresponding side edges of each mount have a first combining structure, and the positioning portions of the assembly element have multiple surfaces facing to each other, each of the surfaces has a second combining structure. The first combining structures are adapted to be combined with the second combining structures. The first combining structures may be recesses or ribs, and the second combining structures may be corresponding ribs or recesses that capable of engaging the first combining structures.

In the assembly structure of electronic device in an embodiment of the invention, each assembly element includes a body and a nut. The body has the positioning portions, and the nut is embedded in the body to form the locking portion. In addition, the assembling hole is also formed in the nut.

In the assembly structure of electronic device in an embodiment of the invention, each assembly element further has a locating portion, and the locating portion is combined with the second case to improve the combination stability of the assembly element on the second case.

In the assembly structure of electronic device in an embodiment of the invention, each of the surfaces of the locating portions facing the second case has a first locating structure, and the surfaces of the second case facing the locating portions have a plurality of second locating structures that capable of engaging the first locating structures. The first locating structures are recesses or ribs, and the second locating structures are ribs or recesses that capable of engaging the first locating structures.

In the assembly structure of electronic device in an embodiment of the invention, the second case has an inner surface and at least one support block protruding from the inner surface, and when the assembly element is fixed to the second case, the support block supports the assembly element.

In the assembly structure of electronic device in an embodiment of the invention, the locking elements are screws including self-tapping screws or normal screws.

Based on the illustration above, in the assembly element of the assembly structure of electronic device in accordance with present invention, the locking element is throughout threaded with the first case, the second case and the assembly element, and therefore the combination stability of the first case and the second case is increased. Notely, the assembly element may be fixed on the second case to wait for securing of the locking elements.

These and other features, aspects and advantages of the present invention will become better understood with regard to the following description, appended claims, and accompanying drawings.

### BRIEF DESCRIPTION OF THE DRAWINGS

FIG. 1 is an exploded diagram showing an upper case, a lower case and a screw in a conventional electronic device;

FIG. 2 is a schematic diagram showing a lower case in another conventional electronic device;

FIG. 3 is a schematic diagram showing the assembly structure of electronic device in a first embodiment of the invention;

FIG. 4 is a schematic diagram showing the second case in FIG. 3;

FIG. 5 is an exploded diagram showing the assembly element in a second embodiment of the invention;

FIG. 6 is an assembly diagram showing the assembly element in FIG. 5;

FIG. 7 is a schematic diagram showing the assembly structure of electronic device utilizing the assembly element in FIG. 5;

FIG. 8 is a schematic diagram showing the second case of the assembly structure of electronic device in a third embodiment of the invention; and

FIG. 9 is a schematic diagram showing the assembly element in the embodiment.

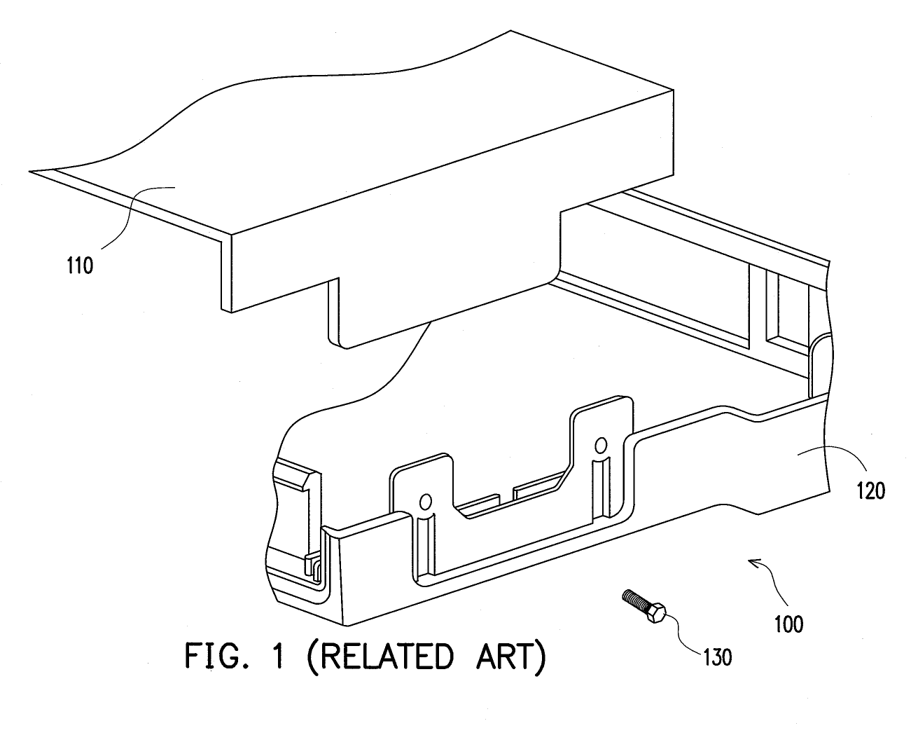

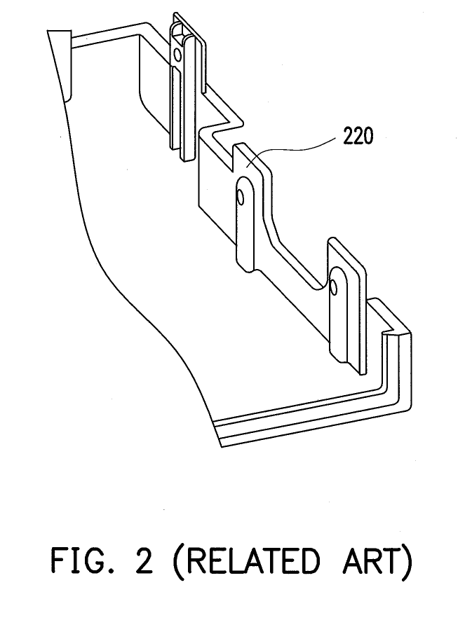

### DETAILED DESCRIPTION OF THE EMBODIMENTS

### The First Embodiment

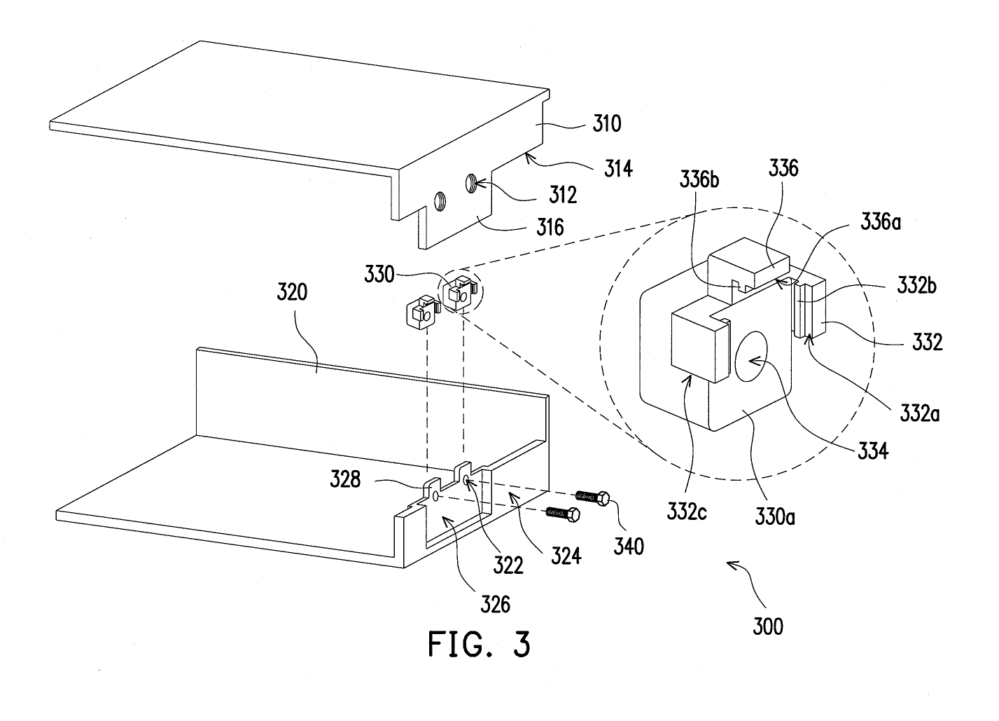

FIG. 3 is a schematic diagram showing the assembly structure of electronic device in a first embodiment of the invention. As shown in FIG. 3, the assembly structure of electronic device 300 in the embodiment includes a first case 310, a second case 320, a plurality of assembly elements 330 and a plurality of locking elements 340. The first case 310 has at least one first combining portion 312 (there are two in FIG. 3), and the second case 320 has at least one second combining portion 322 (such as two shown in FIG. 3), and each assembly element 330 has a plurality of positioning portions 332 and a locking portion 334. The positioning portions 332 preferably formed vertically on the assembly element 330, and engage with the second case 320 to position the assembly element 330 on the second case 320. The first combining portion 312 of the first case 310 and the second combining portion 322 of the second case 320 are correspondingly superposed when the first case 310 and the second case 320 are assembled. Each locking element 340 passes through the first combining portion 312 of the first case 310 and the second combining portion 322 of the second case 320, and fixes in the locking portion 334 of the assembly element 330.

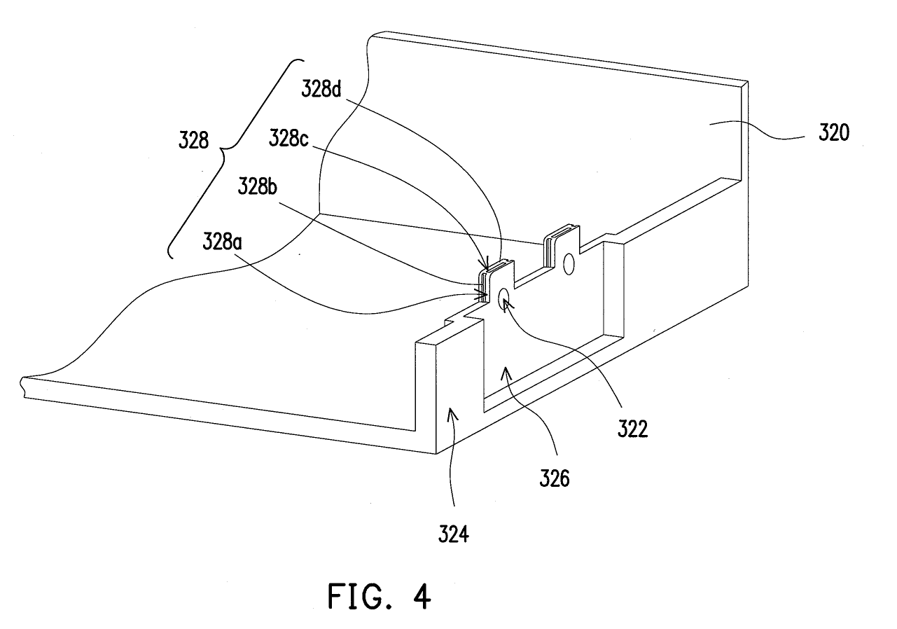

Corresponding threaded holes are formed on the first combining portion 312 and the second combining portion 322. The locking portion 334 has an assembling hole, and the locking elements 340 are screws. FIG. 4 is a schematic diagram showing the second case in FIG. 3. As shown in FIG. 3 and FIG. 4, the second case 320 has an outer surface 324 and an indentation portion 326 formed on the outer surface. The first case 310 has a contact edge 314 abutting the second case 320 and a protrusion portion 316 protruding from the contact edge 314. When the first case 310 abuts against the second case 320, the contact edge 314 of the first case 310 contacts the second case 320, and the protrusion portion 316 is received in the indentation portion 326. In addition, the assembly element 330 further has a body 330a, and two positioning portions 332 protrude from the body 330a and have two surfaces 332a facing each other. The second case 320 further has two mounts 328 to improve the combination stability of the positioning portions 332 of the assembly element 330 on the second case 320.

To combine the positioning portions 332 of the assembly element 330 with the second case 320, the mount 328 may engage with two positioning portions 332 of the assembly element 330, and a bottom surface 332c of each positioning portion 332 abuts against the second case 320. In addition, each of two corresponding side edges 328a of each mount 328 has a first combining structure 328b, respectively, and each of the surfaces 332a facing each other of the two positioning portions 332 has a second combining structure 332b, respectively. In the embodiment, the first combining structure 328b is a recess and the second combining structure 332b is a rib to assemble the assembly element 330 to the second case 320 using the combination of the rib and the recess. However, a skilled person in the art may flexibly change the shapes of the first combining structure 328b and the second combining structure 332b according to desires, and for example, inversely, the first combining structure 328b may be a rib, and the second combining structure 332b may be a recess, which do not depart from the spirit of the invention.

In addition, the second combining portion 322 in FIG. 3 and FIG. 4 is located in the mount 328, and a skilled person in the art may change the position of the second combining portion 322 according to user desires.

In addition, each assembly element 330 further has a locating portion 336 that transversely formed on the assembly element 330, and the locating portion 336 engages the second case 320 to improve the combination stability of the assembly element 330 on the second case 320. The locating portion 336 protrudes from the body 300a and is located at the same side of the body 300a with the positioning portion 332. The surface of each locating portion 336 combining with the second case 320 has a first locating structure 336b, and the surface of the second case 320 combining with the locating portion 336 has a second locating structure 328d being able to engage with the first locating structure 336b. In the embodiment, the second locating structure 328d is disposed at the surface 328c where the mount 328 is combined with the first locating structure 336b. In addition, the first locating structure 336b is a rib and the second locating structure 328d is a recess. A skilled person in the art may flexibly change the shapes of the first locating structure 336b and the second locating structure 328d according to user desires, which does not depart from the spirit of disposing the locating structure.

As shown in FIG. 3, when the user wants to assemble the first case 310 and the second case 320, the assembly element 330 is positioned to the second case 320 in advance. In detail, the first combining structure 332b of positioning portion 332 which is a rib slides into the second combining structure 328b at the surface 328a of the mount 328 which is a recess. That is, the mount 328 is located between the two positioning portions 332. Further, the bottom surface 332c of the positioning portion 332 abuts against the second case 320. Thus, the assembly element 300 can only move along the sliding direction upward or downward, and it cannot move along a direction vertical to the sliding direction leftward or rightward. In addition, the first locating structure 336b of the locating portion 336 may be assembled with the second locating structure 328d of the second case 320 to improve the combination stability of the assembly element 330 on the second case 320. The first locating structure 336b may be closely assembled to the second locating structure 328d, and thus if no external force applies to separate the assembly element 330 and the second case 320, the assembly element 330 does not drop from the second case 320.

Then, the first case 310 is disposed on the second case 320, and the protrusion portion 316 of the first case 310 is received in the indentation portion 326 of the second case 320. The locking element 340 passes through the first combining portion 312 and the second combining portion 322 which have corresponding threaded holes, and fixed in the assembling hole of the locking portion 334. such that the locking element 340 is throughout threaded with the first case 310, the second case 320 and the assembly element 330, and therefore the combination stability of the first case 310 and the second case 320 is increased. Compared with the conventional technique without the assembly element 330 in the invention, since the body 330a of the assembly element 330 in the invention has thickness, the number of the screwed teeth of the locking element 340 which are screwed is more, and the number of the screwed teeth is enough to make the first case 310 and the second case 320 assembled to each other firmly, and the tooth portion is not broken easily.

Particularly, the assembly element 330 may positioned on the second case 320 firmly to wait for insertion of the locking element 340, no need extra support of hands or tools and therefore provide convenience. By using the assembly element 330 in the embodiment, when the first case 310 abuts against the second case 320, a whole thickness of the second case 320 deem to be increased so as to improve the combination stability.

In addition, the combination of the first locating structure 336b of the locating portion 336 and the second locating structure 328d of the second case 320 may improve the combination stability of the assembly element 330 on the second case 320 to prevent the assembly element 330 from dropping.

From above, the combination stability of the first case 310 and the second case 320 is improved, and outer appearance of the first case 310 and the second case 320 that combined with each other are not affected. Notely, the assembly element 330 is disposed at an inner part of the second case 320, and the thickness of the body 330a may be changed according to the user's desire.

### The Second Embodiment

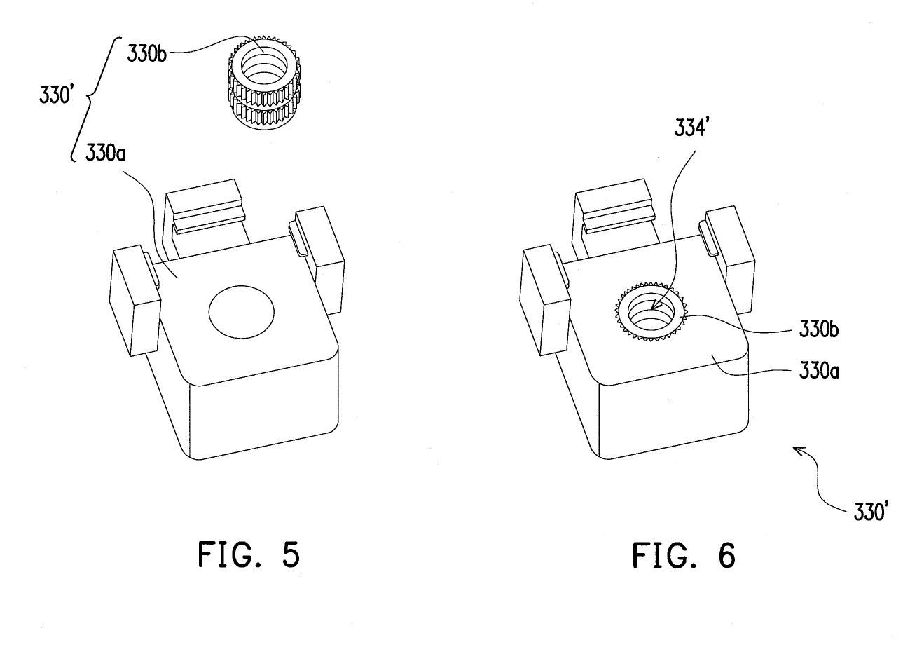

The second embodiment is basically similar with the first embodiment, and thus the same or similar symbols denote the same or similar elements. FIG. 5 is an exploded diagram showing the assembly element in a second embodiment of the invention. FIG. 6 is an assembly diagram showing the assembly element in FIG. 5. As shown in FIG. 5 and FIG. 6, the difference between the second embodiment and the first embodiment is that the assembly element 330′ in the embodiment includes a body 330a and a nut 330b. The assembling hole is formed in the nut 330b, and the nut 330b is embedded in the body 330a to form the locking portion 334′. In detail, the nut 330b is heated first, and then the heated nut 330b is inserted in the body 330a. Since the body 330a is made of plastic, the heated nut 330b may melt and engage in the body 330a. After the nut 330b is cool, it is then fixed in the body 330a.

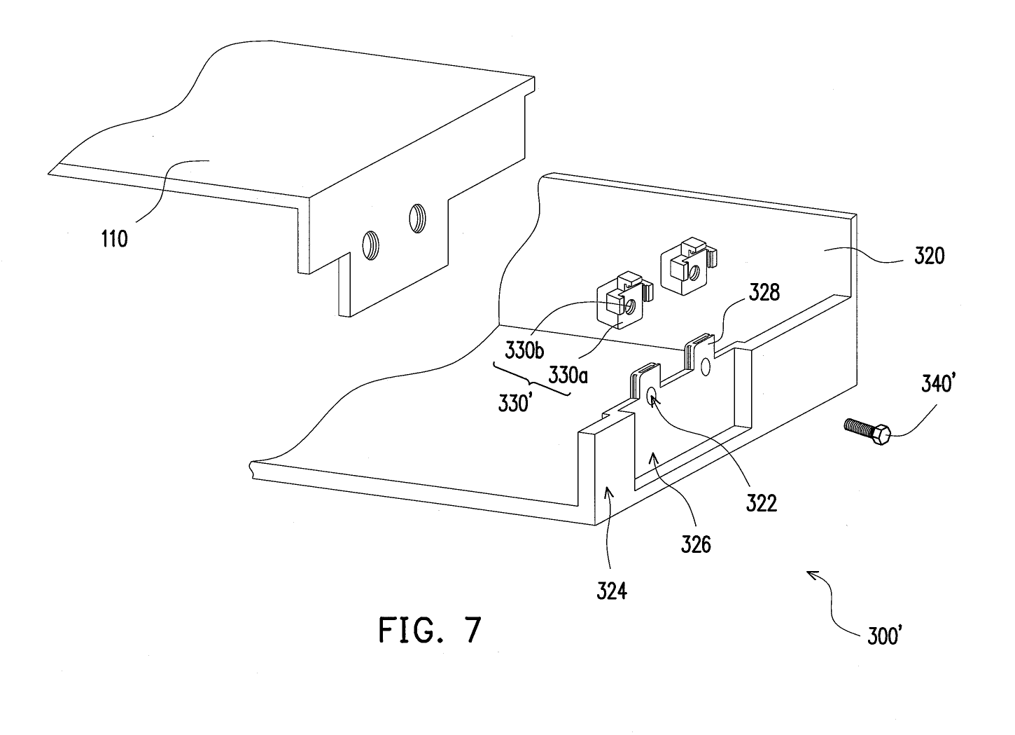

FIG. 7 is a schematic diagram showing the assembly structure of electronic device utilizing the assembly element in FIG. 5. As shown in FIG. 7, the locking element 340′ in the embodiment may be normal screws that correspond to the internal threads of the nut 330b.

### The Third Embodiment

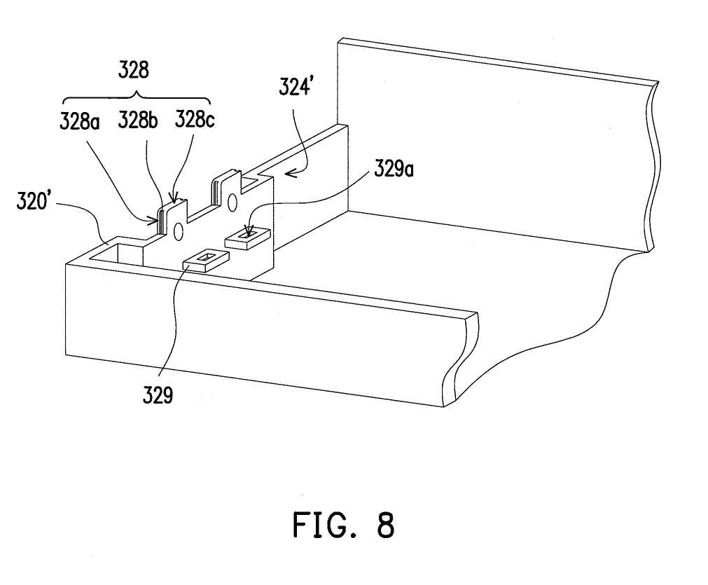

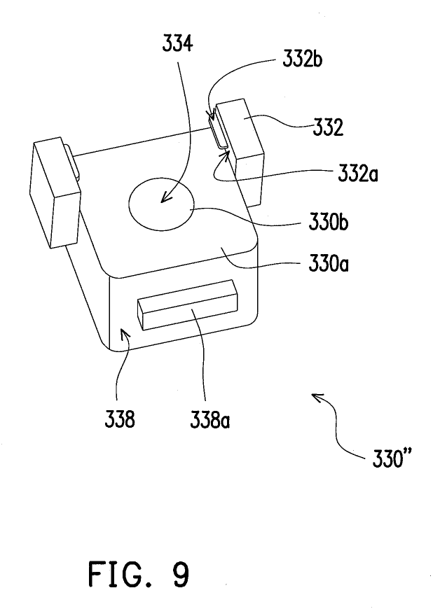

FIG. 8 is a schematic diagram showing the second case of the assembly structure of electronic device in a third embodiment of the invention. FIG. 9 is a schematic diagram showing the assembly element in the embodiment. As shown in FIG. 8 and FIG. 9, the second case 320′ has an inner surface 324′ and at least one support block 329. The support block 329 protrudes from the inner surface 324′. The assembly element 330″ has a bottom surface 338 contacting the support block 329. In addition, the support block 329 further has a first locating structure 329a, and the bottom surface 338 of the assembly element 330″ has a second locating structure 338a. The first locating structure 329a in the embodiment is a recess, and the second locating structure 338a is a rib. When the assembly element 330″ is assembled to the second case 320′, the support block 329 supports the assembly element 330″, and the engagement between the first locating structure 329a and the second locating structure 338a may improve the combination stability of the assembly element 330″ on the second case 320′.

To sum up, the assembly structure of electronic device in the invention has advantages as below:

Firstly, the assembly element may be positioned on the second case for securing with the locking element. Thus, when the first case covers the second case, the user does not need to hold the assembly element with a hand or a tool, which cannot be achieved in the conventional technology.

Secondly, the assembly element may increase the assembling thickness when the first case and the second case are mounted to each other. Thus the locking element may be throughout engaged, thus enhance the combination stability.

Thirdly, the assembly element is disposed at the inner part of the second case, thus the appearance of the case is not affected.

Fourthly, the thickness of the body of the assembly element may be changed according to the user's desires, which is more convenient for the user to use.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. An assembly structure of electronic device comprising:
a first case having at least one first combining portion;
a second case having at least one second combining portion;
at least one assembly element having a plurality of positioning portions and a locking portion, wherein the positioning portions combine with the second case to position the assembly elements on the second case; and
at least one locking element passing through the first combining portion and the second combining portion and fixed in the locking portion.

2. The assembly structure of electronic device according to claim 1, wherein the first combining portion and the second combining portion have corresponding threaded holes, respectively, and the locking portion has a corresponding assembling hole.

3. The assembly structure of electronic device according to claim 1, wherein the second case has an outer surface and an indentation portion formed at the outer surface; the first case has a contact edge and a protrusion portion protruding from the contact edge and received in the indentation portion.

4. The assembly structure of electronic device according to claim 1, wherein the second case has at least one mount engaging with the positioning portions of the assembly element; and a bottom surface of each positioning portion abuts against an edge of the second case.

5. The assembly structure of electronic device according to claim 4, wherein the mount has at least two first combining structures formed in two side edges; each positioning portion of the assembly element has a second combining structure; and the first combining structures engage with the second combining structures.

6. The assembly structure of electronic device according to claim 5, wherein the first combining structures are recesses, and the second combining structures are ribs that capable of engaging the first combining structures.

7. The assembly structure of electronic device according to claim 2, wherein each of the assembly elements comprises:
a body having the positioning portions; and
a nut embedded in the body'to form the locking portion, wherein the assembling hole is formed in the nut

8. The assembly structure of electronic device according to claim 1, wherein the assembly element further has a locating portion engaging with the second case to improve the combination stability of the assembly element on the second case.

9. The assembly structure of electronic device according to claim 8, wherein the locating portion has a first locating structure; and the second case have at least one second locating structure that capable of engaging the first locating structure of the locating portion.

10. The assembly structure of electronic device according to claim 9, wherein the first locating structure is recess, and the second locating structure is rib that capable of engaging the first locating structure.

11. The assembly structure of electronic device according to claim 1, wherein the second case has an inner surface and at least one support block protruding from the inner surface and supporting the assembly element.

12. The assembly structure of electronic device according to claim 1, wherein the locking elements are screws.
